(19) United States
(12) Patent Application Publication
(10) Pub. No.: US 2025/0328075 A1
(43) Pub. Date: Oct. 23, 2025

(54) PHOTOCURABLE COMPOSITION FOR FORMING AN IMPRINT LITHOGRAPHY TEMPLATE

(71) Applicant: CANON KABUSHIKI KAISHA, Tokyo (JP)

(72) Inventors: Fen WAN, Austin, TX (US); Weijun LIU, Cedar Park, TX (US); Caroline M. MCCUISTION, Austin, TX (US)

(21) Appl. No.: 18/640,450

(22) Filed: Apr. 19, 2024

(51) Int. Cl. G03F 7/027; G03F 7/00

(52) U.S. Cl. CPC G03F 7/027; G03F 7/0002

(57) ABSTRACT

A photocurable composition can comprising a polymerizable material and at least one photoinitiator, wherein the polymerizable material can comprise at least one first monomer and at least one second monomer, the at least one first monomer including a multi-functional fluorine-containing monomer and the at least one second monomer being essentially free of fluorine; the polymerizable material comprises fluorine in an amount of at least 30 wt % based on the total weight of the polymerizable material; and a viscosity of the photocurable composition is not greater than 30 mPa·s at 23° C. The photocurable composition is suitable for forming an imprint lithography template comprising a backing layer and a patterned layer, wherein that patterned layer may have a reduced modulus of at least 1 GPa and a water contact angle of at least 70°.

### FIELD OF THE DISCLOSURE

The present disclosure relates to a photocurable composition, particularly to a photocurable composition for forming an imprint lithography template.

### BACKGROUND

Nanoimprint lithography (NIL) involves the use of patterned templates having a high sub-10 nm resolution. Typically, an expensive mother mask or mother template is used to form patterned daughter templates, and the daughter templates are employed to transfer a desired pattern unto a wafer. A daughter template (herein also called imprint lithography template) can have a two-layer structure: a quartz backing and a patterned polymeric layer placed on top of the quartz backing. The requirements for photocurable compositions to make the patterned layer are complex, involving a balance between low viscosity, good spreading behavior, fast curing, good releasability of the mother-template after curing, and high mechanical strength after the curing.

There exists a need for improved photocurable compositions which meet the desired key parameters for forming soft patterned molds usable for NIL processing such that lowered costs of ownership (CoO) can be obtained, and products having a high thermal stability and mechanical strength after the curing.

### SUMMARY

In one embodiment, a photocurable composition can comprise a polymerizable material and at least one photoinitiator, wherein the polymerizable material comprises at least one first monomer and at least one second monomer, the at least one first monomer including a multi-functional fluorine-containing monomer and the at least one second monomer being essentially free of fluorine; the polymerizable material comprises fluorine in an amount of at least 30 wt % based on the total weight of the polymerizable material; and a viscosity of the photocurable composition is not greater than 30 mPa·s at 23° C.

In one aspect, the first monomer or the photocurable composition can comprise at least two functional groups selected from an acrylate group, a vinyl group, or a combination thereof.

In another aspect, a vapor pressure of the first monomer may be not greater than 0.5 torr at 25° C.

In a particular aspect, the first multi-functional fluorine-containing monomer can have a structure of formula (1):

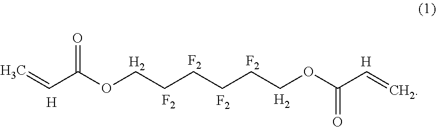

In a further aspect of the photocurable composition, the amount of the at least one first monomer can be at least 20 wt % based on the total weight of the polymerizable material. In a particular aspect, the amount of the at least one first monomer can be least 40 wt % based on the total weight of the polymerizable material.

In one embodiment, the polymerizable material of the photocurable composition can further comprise at least one third monomer, the at least one third monomer being a mono-functional fluorine-containing monomer.

In one aspect, the amount of the at least one third monomer can be at least 20 wt % based on the total weight of the polymerizable material.

In another aspect, the third monomer of the photocurable composition can be selected from 1H,1H-perfluoro-n-octyl acrylate; 1H,1H-perfluoro-n-decyl acrylate; pentafluorophenyl acrylate; pentafluorobenzyl acrylate; 1H,1H,7H-dodecafluoroheptyl acrylate; 1H,1H,2H,2H-tridecafluorooctyl acrylate; (perfluorooctyl)ethyl acrylate, or any combination thereof.

In a further aspect, the amount of the at least one second monomer of the polymerizable material can be at least 20 wt % based on the total weight of the polymerizable material.

In a particular aspect, the at least one second monomer can include a mono-functional acrylate monomer, a multi-functional acrylate monomer, or a combination thereof. In a certain particular aspect, the at least one second monomer can include a multi-functional acrylate monomer.

In another certain aspect of the photocurable composition, the polymerizable material can consist essentially of the multi-functional fluorine-containing monomer and the second monomer being essentially free of fluorine, wherein the second monomer can be a di-functional acrylate monomer, and an amount of the multi-functional fluorine monomer can be at least 70 wt % based on the total weight of the polymerizable material.

In one embodiment of the photocurable composition, the amount of the polymerizable material can be at least 90 wt % based on the total weight of the photocurable composition.

In one aspect, the photocurable composition can further comprise a non-fluorine containing surfactant, and the photocurable composition may be essentially free of a fluorine-containing surfactant.

In another aspect, the molecular weight of the multi-functional fluorine-containing monomer may be not greater than 600 g/mol.

In one embodiment, an imprint lithography template can comprise a backing layer and a patterned layer overlying the backing layer, wherein the patterned layer can be formed from the photocurable composition described above.

In one aspect of the imprint lithography template, the patterned layer can have a reduced modulus of at least 1 GPa.

In another aspect of the imprint lithography template, the water contact angle to the patterned layer can be at least 70°.

In one embodiment, a method of forming an imprint lithography template can comprise: applying a layer of a photocurable composition on a backing layer, wherein the photocurable composition can comprise a polymerizable material and at least one photoinitiator, the polymerizable material comprises at least one first monomer and at least one second monomer, the at least one first monomer including a multi-functional fluorine-containing monomer and the at least one second monomer being essentially free of fluorine, the polymerizable material comprises fluorine in an amount of at least 30 wt % based on the total weight of the polymerizable material, and a viscosity of the photocurable composition is not greater than 30 mPa·s; bringing the photocurable composition into contact with a template; irradiating the photocurable composition with light to form a photo-cured patterned layer; and removing the template from the patterned layer.

### BRIEF DESCRIPTION OF THE DRAWINGS

Embodiments are illustrated by way of example and are not limited in the accompanying FIGURES.

FIG. 1 includes a line drawing illustrating an imprint lithography template according to one embodiment.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

In one embodiment, the present disclosure is directed to a photocurable composition comprising a polymerizable material and at least one photoinitiator, wherein the polymerizable material comprises at least one first monomer and at least one second monomer. The at least one first monomer can include a multi-functional fluorine-containing monomer and the at least one second monomer may be essentially free of fluorine. The amount of the polymerizable material of the photocurable composition can comprise fluorine in an amount of at least 30 wt % based on the total weight of the polymerizable material; and the viscosity of the photocurable composition may be not greater than 30 mPa·s at 23° C.

The photocurable composition of the present disclosure (herein also called “resist”) can be designed for the fabrication of a bound soft mold with fine pattern. As used herein, the term “bound soft mold” refers to a new type of mask fabrication, also called a quartz-polymer-stack, which contains a quartz blank as supporting layer, herein also called “backing layer,” and contains a bonded polymeric layer on top of the quartz support, wherein the polymeric layer can comprise a certain pattern in order to function as a template for nanoimprint lithography (NIL) processing, herein also called “patterned layer.” The pattern in the polymeric layer of the bound soft mold can be made by patterning using a nanoimprint method.

The photocurable composition of the present disclosure can be suitable for the manufacturing of bound soft molds by forming patterned polymeric layers having a sub-10 nm resolution, and thereby may replace expensive quartz templates. In order to achieve this, the photocurable composition can combine the following parameters: being ink-jettable, which means having a low viscosity and good spreading behavior; a good release performance during the mold fabrication and pattern transfer; desired mechanical properties after curing, such as a high reduced modulus, hardness, and flexibility, which can withstand at least 400 imprinting cycles.

In one embodiment, the multi-functional fluorine-containing monomer (the first monomer) of the polymerizable material of the photocurable composition can comprise at least two functional groups selected from an acrylate group, a vinyl group, or a combination thereof. In a particular embodiment, the first monomer can comprise two acrylate groups.

As used herein, the term acrylate group means unsubstituted or substituted acrylate groups, for example, it includes acrylate groups containing an alkyl substitution, such as a methacrylate group.

In a certain aspect, the first monomer can have the structure of formula (1):

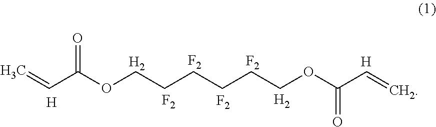

In one aspect, the vapor pressure at 25° C. of the multi-functional fluorine-containing monomer of the polymerizable material can be not greater than 0.5 torr at standard ambient temperature and pressure (SATP), such as not greater than 0.2 torr, or not greater than 0.1 torr, or not greater than 0.06 torr, or not greater than 0.01 torr, or not greater than 0.005 torr. In another aspect, the vapor pressure of the first monomer may be at least 0.0001 torr or at least 0.001 torr.

In a particular embodiment, the molecular weight of the multi-functional fluorine-containing monomer may be not greater than 600 g/mol, or not greater than 500 g/mol, or not greater than 400 g/mol. In another aspect, the molecular weight of the first monomer can be at least at least 250 g/mol, or at least 300 g/mol, or at least 350 g/mol.

The amount of the multi-functional fluorine-containing monomer can be at least 20 wt % based on the total weight of the polymerizable material, or at least 30 wt %, or at least 35 wt %, or at least 40 wt %, or at least 50 wt %, or at least 60 wt %, or at least 70 wt %, or at least 80 wt %. In another aspect, the amount of the multi-functional fluorine containing monomer may be not greater than 85 wt % based on the total weight of the polymerizable material, or not greater than 80 wt %, or not greater than 70 wt %, or not greater than 60 wt %, or not greater than 50 wt % based on the total weight of the polymerizable material.

In another embodiment, the polymerizable material can comprise at least one third monomer, wherein the at least one third monomer can be a mono-functional fluorine-containing monomer.

In a particular aspect, non-limiting examples of the mono-functional fluorine-containing monomer can be 1H,1H-perfluoro-n-octyl acrylate; 1H,1H-perfluoro-n-decyl acrylate; pentafluorophenyl acrylate; pentafluorobenzyl acrylate; 1H,1H,7H-dodecafluoroheptyl acrylate; 1H,1H,2H,2H-tridecafluorooctyl acrylate; (perfluorooctyl)ethyl acrylate, or any combination thereof.

The amount of the mono-functional fluorine-containing monomer (herein also called third monomer) can be at least 20 wt % based on the total weight of the polymerizable material, or at least 25 wt %, or at least 30 wt %, or at least 35 wt %, or at least 40 wt % based on the total weight of the polymerizable material. In another aspect, the amount of the third monomer may be not greater than 50 wt %, or not greater than 45 wt %, or not greater than 40 wt %, or not greater than 35 wt %, or not greater than 30 wt % based on the total weight of the polymerizable material.

The second monomer of the polymerizable material of the photocurable composition can be essentially free of fluorine. As used herein, essentially free of fluorine means that the monomer contains fluorine in an amount of less than 1 wt % based on the total weight of the second monomer, or less than 0.5 wt %, or less than 0.1 wt %, or being free of fluorine except for unavoidable impurities.

In one aspect, the second monomer can be a mono-functional or a multi-functional monomer. In a particular aspect, the second monomer can be a di-functional, or a three-functional acrylate monomer, or a combination thereof. In a certain particular aspect, the second monomer can be a three-functional acrylate monomer.

Non-limiting examples of structures suitable for the second monomer can be, e.g.,

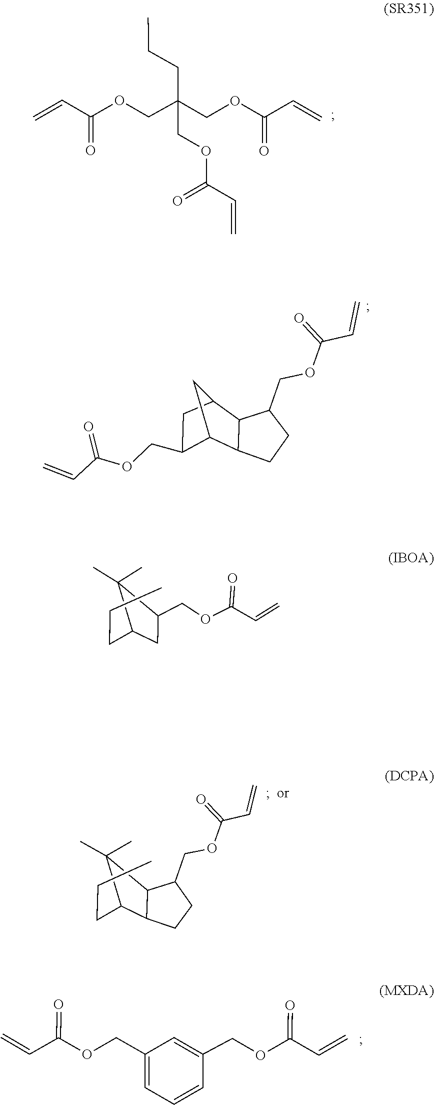

or any combination thereof.

In a particular aspect, the polymerizable material can consist essentially of the first monomer and the second monomer, wherein the first monomer may be a di-functional fluorine-containing monomer and the second monomer may be a three-functional acrylate monomer (not containing fluorine), and an amount of the multi-functional fluorine-containing monomer can be at least 70 wt % based on the total weight of the polymerizable material.

In one embodiment, the type and amount of fluorine-containing monomers can be adjusted such that a total amount of fluorine in the polymerizable material can be at least 30 wt % based on the total weight of the polymerizable material, such as at least 32 wt %, or at least 35 wt %, or at least 38 wt %, or at least 40 wt %. In another aspect, the fluorine content of the polymerizable material may be not greater than 55 wt %, or not greater than 50 wt %, or not greater than 45 wt %, or not greater than 43 wt %, or not greater than 40 wt % based on the total weight of the polymerizable material.

The amount of polymerizable material of the photocurable composition can be at least 50 wt % based on the total weight of the photocurable composition, such as at least 60 wt %, at least 70 wt %, at least 80 wt %, at least 85 wt %, at least 90 wt %, or at least 94 wt %. In another aspect, the amount of polymerizable material may be not greater than 99 wt %, such as not greater than 98 wt %, or not greater than 96 wt %, or not greater than 94 wt %, or not greater than 90 wt % based on the total weight of the photocurable composition. The amount of polymerizable material can be a value between any of the minimum and maximum values noted above. In a particular aspect, the amount of the polymerizable material can be at least 80 wt % and not greater than 94 wt %.

In one aspect, the viscosity of the photocurable composition of the present disclosure can be not greater than 50 mPa·s, such as not greater than 40 mPa·s, not greater than 30 mPa·s, not greater than 25 mPa·s, not greater than 20 mPa·s. In other certain embodiments, the viscosity may be at least 2 mPa·s. or at least 3 mPa·s, or at least 5 mPa·s. As used herein, all viscosity values relate to viscosities measured at a temperature of 23° C. with the Brookfield method using a Brookfield Viscometer.

In one embodiment, the photocurable composition of the present disclosure can be essentially free of a solvent.

As used herein, if not indicated otherwise, the term solvent relates to a compound which can dissolve or disperse the polymerizable monomers and hindered stabilizer but does not itself polymerize during the photo-curing of the photocurable composition. The term “essentially free of a solvent” means herein an amount of solvent being not greater than 5 wt % based on the total weight of the photocurable composition. In a certain particular aspect, the amount of the solvent can be not greater than 3 wt %, not greater than 2 wt %, not greater than 1 wt %, or the photocurable composition can be free of a solvent, except for unavoidable impurities.

In order to initiate the photo-curing of the composition if exposed to light, one or more photoinitiators can be included in the photocurable composition.

In a certain aspect, the curing can be also conducted by a combination of light and heat curing.

The photocurable composition can further contain one or more optional additives. Non-limiting examples of optional additives can be stabilizers, dispersants, solvents, surfactants, inhibitors, or any combination thereof.

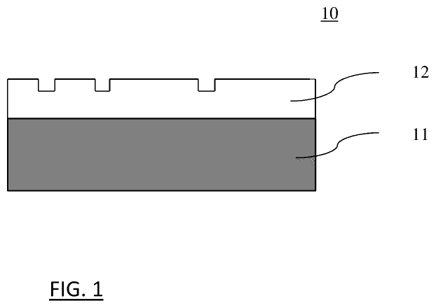

In another embodiment, as shown in FIG. 1, the present disclosure is directed to an imprint lithography template (10), comprising a backing layer (11) and a patterned layer (12). The imprint lithography template can further contain an adhesion layer (not shown) directly overlying the backing layer (11), which can improve binding of the patterned layer (12) to the backing layer (11). In one aspect, the patterned layer can be formed by curing the above-described photocurable composition of the present disclosure.

In one aspect of the imprint lithography template, a material of the backing layer can be quartz or silica.

In another aspect of the imprint lithography template (10), a water contact angle of the patterned layer (12) may be at least 70°, or at least 72°, or at least 74°, or at least 76°, or at least 78°. In another aspect, the water contact angle may be and not greater than 88°, or not greater than 85°.

The patterned layer (12) can have a suitable mechanical strength to withstand a plurality of imprinting cycles without quality loss of the imprinting. In one aspect, the imprint lithography template of the present disclosure can be repeatedly used for imprinting at least 100 times, or at least 200 times, or at least 400 times, or at least 800 times, or at least 1000 times.

In a particular aspect, the material of the patterned layer may have a reduced modulus of at least 1 GPa, or at least 1.5 GPa, or at least 1.8 GPa, or at least 2 GPa. In another aspect, the reduced modulus may be not greater than 5 GPa, or not greater than 4 GPa, or not greater than 3 GPa.

In a further particular aspect, a material of the patterned layer (12) can have a hardness of at least 0.15 GPa, or at least 0.2 GPa, or at least 0.25 GPa, or at least 0.30 GPa, or at least 0.35 GPa. In another aspect, the hardness may be not greater than 3 GPa, or not greater than 2 GPa, or not greater than 1.5 GPa, or not greater than 1.0 GPa, or not greater than 0.5 GPa.

In yet a further aspect, the surface free energy (SFE) of the patterned layer (12) may be not greater than 45 mJ/m², or not greater than 42 mJ/m², or not greater than 40 mJ/m², or not greater than 38 mJ/m². In another aspect the SFE may be at least 20 mJ/m², or at least 25 mJ/m², or at least 30 mJ/m².

In another aspect, the glass transition temperature (T_{g}) of the material of the patterned layer (12) can be at least 60° C., or at least 65° C., or at least 70° C., or at least 75° C. In a further aspect, the T_{g} may be not greater than 130° C., or not greater than 110° C., or not greater than 100° C., or not greater than 90° C., or not greater than 80° C.

The present disclosure is further directed to a method of forming the above-described imprint lithography template. The method can comprise applying a layer of the photocurable composition described above over a substrate (herein also called backing layer), bringing the photocurable composition into contact with a template (mother template); irradiating the photocurable composition with light to form a photo-cured patterned layer; and removing the template from the photo-cured patterned layer.

As further demonstrated in the examples, it has been surprisingly observed that photocurable compositions containing certain types and combinations of fluorine-containing monomers and non-fluorine containing monomers can have advantages for forming high quality patterned layers for use as a soft bond mold in nanoimprint lithography processes.

### EXAMPLES

The following non-limiting examples illustrate the concepts as described herein.

### Example 1

A series of photocurable compositions was prepared with the aim of having a fluorine content of at least 30 wt % based on the total weight of the polymerizable material, and having a property profile being suitable for forming high-quality bound soft molds.

The polymerizable material of the photocurable compositions contained varying monomer combinations of two or three different monomer types:
1) a first monomer type being a multi-functional fluorine-containing monomer, for which was used 1H, 6H, 6H-perfluoro-1,6-hexyl diacrylate (PHDA);
2) a second monomer type being essentially free of fluorine and selected from: isobornyl acrylate (IBOA), m-xylylene diacrylate (MXDA), dihydro-dicyclo-pentadienyl acrylate (DCPA), and trimethylol propane diacrylate (SR351); and
3) a third monomer type, being a mono-functional fluorine containing monomer and selected from: 1H,1H-perfluoro-n-octyl acrylate (POcA); 1H,1H-perfluoro-n-decyl acrylate (PDeA); and MD7000 (fluorlink).

All photocurable compositions further contained 3 parts of the non-fluorine containing surfactant SA3070. As photoinitiators were used Irgacure 651 or TPO/TPO-L. A summary of the photocurable compositions can be seen in Tables 1 and 2.

Table 1 summarizes all photocurable compositions which were evaluated being representative to the present disclosure (samples S1 to S7), as well as comparative photocurable compositions C1, C2, and C3. Comparative compositions C1 and C2 did not include a polymerizable monomer of type 2, i.e., a monomer which does not containing fluorine, and had not the required mechanical strength; comparative composition C3 did not include a monomer of type 1, i.e., a multi-functional fluorine-containing monomer, but only a monomers falling under type 2 and type 3, and did not reach a fluorine content of at least 30 wt %.

TABLE 1

| | S1 | S2 | S3 | S4 | S5 | S6 | S7 | C1 | C2 | C3 |
|---|---|---|---|---|---|---|---|---|---|---|
| PHDA | 40 | 40 | 40 | 40 | 80 | 25 | 20 | 40 | 40 | 50 |
| POcA | 40 | 40 | | 40 | | 35 | 34 | 60 | 40 | |
| PDeA | | | | | | | | | | |
| MD7000 | | | | | | | | | 20 | |
| IBOA | 20 | | | | | | | | | |
| MXDA | | 20 | | | | | | | | |
| DCPA | | | 20 | | | | | | | |
| SR351A | | | | 20 | 20 | 40 | 46 | | | 46 |
| Irg651 | 3 | 3 | 3 | 3 | | | | 3 | 3 | |
| TPO | | | | | 2 | | | | | |
| TPO-L | | | | | 1 | | | | | |
| SA3070 | 3 | 3 | 3 | 3 | 3 | 3 | 3 | 3 | 3 | |
| F-content [%] | 42 | 42 | 42 | 42 | 33 | 32 | 30 | 54 | 52 | 21 |
| Module [GPa] | 1.59 | 1.74 | 1.64 | 1.6 | 2.3 | 1.9 | 2.0 | 0.78 | 0.57 | 2.8 |
| Hardness [GPa] | 0.16 | 0.23 | 0.22 | 0.25 | 0.39 | 0.32 | 0.34 | 0.11 | 0.09 | 0.47 |
| CA H₂O | 83 | 70 | 74 | 78 | 71 | 77 | 73 | 85 | 85 | 68 |

Table 2 contains a summary of comparative compositions C4 to C10. All these compositions had the disadvantage of being not good mixable, and therefore were not considered suitable for forming a soft mold according to the present disclosure. As used herein, “not mixable” means that the fluorine-containing monomers and the non-fluorine containing acrylate monomers did not dissolve in each other, and a separation into two phases in form of two liquid layers was observed after combining all ingredients of the photocurable composition and standing for one hour or longer.

TABLE 2

| | C4 | C5 | C6 | C7 | C8 | C9 | C10 |
|---|---|---|---|---|---|---|---|
| PHDA | | | | | | | |
| POcA | 35 | | | | 50 | 35 | 35 |
| PDeA | | 80 | 65 | 50 | | | |
| MD7000 | 25 | | | | | 30 | 30 |
| IBOA | | | | | | | |
| MXDA | | | | | | | |
| DCPA | | | | | | | |
| SR351A | 40 | 20 | 35 | 50 | 50 | 25 | 35 |
| Irg651 | 3 | | | | | | |
| TPO | | 2 | 2 | 2 | 2 | 2 | 2 |
| TPO-L | | 1 | 1 | 1 | 1 | 1 | 1 |
| SA3070 | 3 | 3 | 3 | 3 | 3 | 3 | 3 |
| F-content [%] | 35 | 52 | 42 | 33 | 31 | 38 | 38 |

From the data in table 2 can be concluded that if no multi-functional fluorine containing monomer PHDA was used, and only mono-functional monomers and non-fluorine containing monomers were combined, although a high fluorine content above 30 wt % could be reached, these samples were not properly mixable and therefore not usable as photocurable compositions for preparing soft-bond molds (see comparative samples C4 to C10).

The following is a detailed discussion of the measured property profile of the photocurable compositions, such as contact angle to a substrate, surface tension, viscosity, and after photo-curing to solid polymeric films the reduced modulus, hardness, water contact angle, surface free energy (SFE), release force and glass transition temperature.

### Contact Angle and Surface Tension of Liquid Photocurable Compositions

To evaluate the drop spreading of the photocurable compositions, the surface tension of representative photocurable compositions and the contact angle to a silica slide containing an adhesion layer coating of acryloxymethyltrimetoxysilane (AMTMS) was measured.

The results of the measurements are shown in Table 3. It can be seen that especially for photocurable compositions S1 and S5, the contact angle to the AMTMS-coated silica slide (AMTS CA) was very low (4.2 and 7.7 degrees), which indicates a good spreading behavior over the mold supporter layer during mold fabrication, which is desirable to obtain a void-free pattern during the mold fabrication.

The trend for a good drop spreading is opposite when evaluating the surface tension in comparison to the AMTS CA. Here, the higher the surface tension, the better the drop spreading. It can be seen from the data in Table 3 that all tested photocurable compositions had a low surface tension, of which the highest values were obtained for photocurable composition S1 and S5.

TABLE 3

| Sample | F [%] | Surfactants | ST [mN/m] | AMTMS CA [°] |
|---|---|---|---|---|
| S1 | 42 | Non-F Surfactant | 16 | 4.2 |
| S5 | 33 | Non-F surfactant | 21.6 | 7.7 |
| C1 | 52 | None | 12.9 | 6.2 |
| C2 | 52 | F-surfactant | 12.6 | 12.1 |
| C2 | 54 | Non-F surfactant | 12.7 | 12.4 |

The data in Table 3 further show that a fluorine-containing surfactant had no further influence on the surface tension or contact angle of the photocurable composition C2. This is an indication that the fluorine-free surfactant SA3070 was efficient, and it is possible to avoid the use of fluorine-containing surfactants for the photocurable compositions of the present disclosure.

### Measurement of Surface Tension:

The surface tension was measured by the Pendant Drop method using a DM-701 contact angle meter made by Kyowa Interface Science Co. Ltd (Japan). For the measurement, a syringe containing the test fluid was loaded on the syringe holder, and a measuring program of the Pendant Drop control panel was started. The SM-701 allows automatic liquid dispensing and drop size control. The drop images were captured and the drop shapes were analyzed with the help of a software program using the Young-Laplace theory to obtain the surface tension.

Measurement of AMTMS contact angle:

For the testing of the AMTMS contact angle, a bare fused silica glass slide was coated with an adhesion layer by applying acryloxymethyltrimetoxysilane (AMTMS), from Gelest, as an adhesion promoter coating.

The AMTS-coated quartz slide was prepared in order to mimic the fused silica support surface during fabrication of bound soft mold. As used herein, the contact angle of the photocurable composition to the AMTMS-coated quartz slide is called “AMTMS contact angle” or “AMTMS CA.”

The AMTMS CA was measured the same way as the below-described water contact angle, except that the photocurable composition replaced the water drop, and the AMTMS coated quartz slide replaced the surface of the photo-cured layer.

### Viscosity of Photocurable Compositions

The viscosities were measured with a Brookfield DV-11+Pro viscometer using spindle #18. For each viscosity measurement, a sample of 6-7 ml was taken, added to the sample chamber and allowed to equilibrate for 15-20 minutes to reach the target temperature of 23° C. The viscosities were measured with spindle #18 at a speed of 135 rpm. For each sample, the measurement was three times repeated and an average value calculated.

For all tested photocurable compositions, the measured viscosities were in the range of 5 to 20 mPa·s at 23° C.

### Reduced Modulus and Hardness

The data of Table 1 show that in order to obtain a sufficient mechanical strength of the formed film (which simulates the bound soft mold) after curing, it was important to combine the multi-functional fluorine-containing monomer together with one of the non-fluorine containing monomers. While sample S5, which contained a combination of 80 wt % multi-functional fluorine containing monomer PHDA and 20 wt % of trimethylol propane diacrylate (SR351), achieved the best mechanical properties and a fluorine content above 30 wt %, it was also possible to obtain a desirable high fluorine content (>30 wt %) and good mechanical strength with the combinations of a multi-functional fluorine-containing monomer (first monomer), a mono-functional fluorine containing monomer (third monomer), and a multi-functional non-fluorine containing monomer (second monomer), see samples S1 to S4, S6, and S7. However, if only fluorine-containing monomers were used as polymerizable material, and non-fluorine containing monomer were excluded, see comparative samples C1 and C2, the obtained material after curing was too soft to be suitable as a mold.

Furthermore, if no multi-functional fluorine containing monomer was used, and only mono-functional monomers and non-fluorine containing monomers were combined, although a high fluorine content of above 30 wt % could be reached, these samples were not properly mixable and therefore not usable.

The reduced modulus (herein also called just modulus) and the hardness of the photo-cured samples (S1 to S7 and C1 to C3) were tested by nanoindentation using a Hysitron TI 950 Triboindenter, which contained software named TriboScan to conduct the data analysis by relying on an integrated Oliver-Pharr method.

A cured film of the test sample (photocurable composition to be tested) was prepared by adding drops on a silicon wafer (Si-wafer) and covering the liquid with a quartz flat mask on to let it spread. When the liquid was spread to the edge of the mesa, a UV intensity of 2 J/cm² at 365 nm was radiated for photo-curing the sample. Thereafter, the mask was removed and a cured film on the Si wafer was left. During the whole process, the temperature was controlled and set to 23° C. For each testing, three drops of two μl liquid of the test sample was added onto the wafer in a regular triangle shape with a space of 10 mm apart of each side to obtain a film having a thickness after of about 3 microns after the curing.

Thereafter, the wafer with the photo-cured film was placed onto the stage of the Triboindenter. A diamond indenter (90 degrees corner tip) was used for conducting the indentation, which was calibrated by a standard fused silica. The reduced modulus Er in GPa was determined by measuring the load P and the displacement h (indentation depth). The indented depth was around 200 nm, and a 5×5 array of points was used to determine an average reduced modulus Er. During indentation, the force was measured from which the loading curves could be obtained. The hardness (H) was calculated according to the following equation:

H=Pₘₐₓ/A_{c}, wherein Pₘₐₓ is the maximum applied force, and A_{c} is the contact area determined by the tip area function.

### Water Contact Angle of Photo-Cured Layers

The water contact angle to the solid layers obtained after photo-curing of samples S1 to S7 was measured in order to evaluate the hydrophobic character of the surfaces, wherein the water contact angle increases with an increase in the hydrophobic character of a surface.

For measuring the water contact angles, photo-cured layers were prepared on fused silica glass slides coated with an adhesion layer to mimic the material of the soft mold. The adhesion layer was prepared by spin coating a mixture of EA7140 (a phenolic methacrylate) from Shin-Nakamura Chemical, and T2059 (a triazine) from Tokyo Chemical Industry, in propylene glycol methyl ether acetate (PGMEA) solution, called herein EAT adhesion layer or EAT-coated fused silica glass slide. The EAT adhesion layer had a thickness of about 5 nm.

The photo-cured layers were made by adding to the EAT-coated fused silica glass slide three drops of 3.5 μl of the photocurable composition set 2 cm apart of each other. A clean quartz slide having a size of 25 mm×75 mm×1 mm was placed on top of the drops and the liquid photocurable composition allowed to fill the entire area covered by the quartz slide. Thereafter, the photocurable composition was cured with UV light using a radiation energy of 2 J/cm². After the photo-curing the top quartz slide was peeled off, and the exposed cured polymeric layer was used for measuring the water contact angle using a Drop master DM-701 contact angle meter (made by Kyowa Interface Science Co. Ltd., Japan). For each contact angle measurement, a water drop of 2 μl was added by the machine to the target surface. Drop images were continuously captured by a CCD camera from the time the water drop touched the target surface. The contact angle was automatically calculated by software associated with the Drop master DM-701 contact angle meter. The data shown in table 1 correspond to the water contact angle at a time of 3 seconds after touching the target surface.

It can be sees that high water contact angles (H₂O CA) to the polymeric layers formed by the compositions of samples S1 to S7 were obtained within a range of 70°-83° (see Table 1). In contrast, comparative sample C3, which had a fluorine content of only 21 wt %, had a contact angle of below 70°, specifically 68°. Although photo-cured comparative samples C1 and C2 also had high water contact angles of even greater than 80° (because of the high fluorine content), the disadvantage of these samples was the low strength of the material obtained after curing.

### Surface Free Energy of Cured Layers

The surface free energy (SFE) was also measured with the Drop master DM-701 described above, by measuring in a first measurement the contact angle of a water and in a second measurement the contact angle of diiodomethane to the target surface (the photo-cured polymeric layers, which correspond to the material of the soft mold). The surface free energy was calculated based on both contact angle values using the Owens-Wendt method with the analysis software FAMAS installed in the Drop Mater DM-701 instrument.

In Table 4, the measured surface free energy for a variety of materials is shown such as: hand-made polymeric layers formed from photocurable composition S1 and S4 (soft molds) on a bare silicon slide, a clean quartz slide, a EAT coated Si-slide, and an AMTMS-coated Si-slide. It can be seen that the lowest surface free energy (SFE) had the soft mold layers formed from photocurable compositions S1 and S4. Not being bound to theory, it is assumed that the fluorine component of the cured materials is located on the surface, which will prevent the penetrating of a resist during its application, which allows a clean separation during nanoimprinting.

TABLE 4

| Sample | SFE [mJ/m²] |
|---|---|
| Sample S1 Imprint | 34 |
| Sample S4 Imprint | 37 |
| Quartz slide | 73 |
| Bare Si-slide | 74 |
| EAT-coated Si-slide | 48 |
| AMTMS-coated Si-slide | 61 |

### Release Force

To fabricate the bound soft mold, a low release force to separate the mother mold (which can be a pre-patterned by EB litho- or photolithography or nanoimprint lithography) is a key parameter to obtain a defect-free pattern replica.

In a first set of experiments, the production process of a bound soft mold was simulated by adding a photocurable composition of a primed quartz slide, covering a liquid layer with a glass slide, photo-curing the photocurable composition, measuring the release force needed to remove the glass slide from the photo-cured layer (the simulated bound soft mold). The testing was conducted using an Instron 5542 instrument. The thickness of the applied liquid layer was about xxx microns, and the liquid layer was photo-cured with a total radiation dosage of 2000 mJ/cm². After the photo-curing a 4-point bending test was conducted according to ASTM D6272 to determine the needed release force for removing the glass slide from the photo-cured layer. A release force of less than 2.0 lbs was considered as corresponding with a high-quality separation, which means a clean separation, wherein the photo-cured layer has not been damaged.

In a second set of experiments, the release force for separating the simulated bound soft mold from a typical imprint resist was measured. As resist was used a photocurable composition containing 65 parts of m-xylene diacrylate, 35 parts of trimethylolpropane triacrylate, 2 parts Irgacure 819 as photoinitiator and 0.5 parts of the surfactant FS2000M1. A liquid layer of the resist was formed by dropping the resist on an adhesion promoter-primed silicon wafer and covered with a simulated bound soft mold (adhesion promoter-primed silicon slides containing photo-cured layers of samples S1-S7). The resist was cured with a radiation dosage of 2000 mJ/cm². Thereafter, the release force of the simulated bound soft mold was measured via the 4-point bending test according to ASTM D6272.

The test results are summarized in Table 5. It can be seen that for both forming processes, a low release force is required.

TABLE 5

| | Release Force [lbs] for | Release Force [lbs] for |
|---|---|---|
| Sample | soft mold fabrication | imprinting with soft mold |
| S1 | 0.66 | 0.82 |
| S2 | 1.12 | |
| S3 | 0.81 | 0.60 |
| S4 | 0.70 | 0.64 |
| S5 | 1.20 | 0.77 |
| S6 | 0.90 | 0.76 |
| S7 | 0.90 | 0.77 |

### Glass Transition Temperature

In order to use the mold for imprinting at room temperature, the material of the mold should have a glass transition temperature or at least 50° C. to avoid deformation due to temperature.

The glass transition temperature was measured by rheometry, using an Anton-Paar MCR-301 rheometer coupled with a Hamamatsu Lightningcure LC8 UV source. The sample was radiated with a UV intensity of 1.00 mW/cm² at 365 nm measured by a Hamamatsu 365 nm UV power meter. Software named RheoPlus was used to control the rheometer and to conduct the data analysis. The temperature was controlled by a Julabo F25-ME water unit and set to 23° C. as starting temperature. For each sample testing, 7 μl test sample was added onto a plate positioned directly underneath the measuring system of the rheometer. Before starting with the UV radiation, the distance between glass plate and measuring unit was reduced to a gap of 0.1 mm. The UV radiation exposure was continued until the storage modulus reached a plateau, and the height of the plateau was recorded as the storage modulus.

After the UV curing was completed, the temperature of the cured sample was increased by controlled heating to measure the change of the storage modulus and loss modulus in dependency to the temperature to obtain the glass transition temperature T_{g}. As glass transition temperature T_{g} was considered the temperature corresponding to the maximal value of Tangent (θ), which is the ratio of storage modulus over loss modulus.

The glass transition temperature measured for samples S4, S5, S6, and S7 can be seen in Table 6. The data show that for tested photocurable compositions the T_{g} was greater than 70° C., which satisfies the T_{g} requirement for a bound soft mold.

TABLE 6

| Sample | Tg [° C.] |
|---|---|
| S4 | 77 |
| S5 | 76 |
| S6 | 89 |
| S7 | 86 |

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material and at least one photoinitiator, wherein
the polymerizable material comprises at least one first monomer and at least one second monomer, the at least one first monomer including a multi-functional fluorine-containing monomer and the at least one second monomer being essentially free of fluorine;
the polymerizable material comprises fluorine in an amount of at least 30 wt % based on the total weight of the polymerizable material; and
a viscosity of the photocurable composition is not greater than 30 mPa·s at 23° C.

2. The photocurable composition of claim 1, wherein the first monomer comprises at least two functional groups selected from an acrylate group, a vinyl group, or a combination thereof.

3. The photocurable composition of claim 1, wherein a vapor pressure of the first monomer is not greater than 0.5 torr at 25° C.

4. The photocurable composition of claim 1, wherein the first monomer has a structure of formula (1):

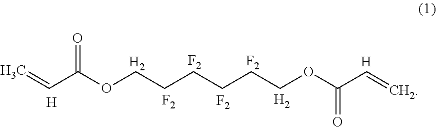

5. The photocurable composition of claim 1, wherein an amount of the at least one first monomer is at least 20 wt % based on the total weight of the polymerizable material.

6. The photocurable composition of claim 5, wherein an amount of the at least one first monomer is at least 40 wt % based on the total weight of the polymerizable material.

7. The photocurable composition of claim 1, wherein the polymerizable material further comprises at least one third monomer, the at least one third monomer being a mono-functional fluorine-containing monomer.

8. The photocurable composition of claim 7, wherein an amount of the at least one third monomer is at least 20 wt % based on the total weight of the polymerizable material.

9. The photocurable composition of claim 7, wherein the third monomer is selected from 1H,1H-perfluoro-n-octyl acrylate; 1H,1H-perfluoro-n-decyl acrylate; pentafluorophenyl acrylate; pentafluorobenzyl acrylate, 1H,1H,7H-dodecafluoroheptyl acrylate; 1H,1H,2H,2H-tridecafluorooctyl acrylate; (perfluorooctyl)ethyl acrylate, or any combination thereof.

10. The photocurable composition of claim 1, wherein an amount of the at least one second monomer is at least 20 wt % based on the total weight of the polymerizable material.

11. The photocurable composition of claim 1, wherein the at least one second monomer includes a mono-functional acrylate monomer, a multi-functional acrylate monomer, or a combination thereof.

12. The photocurable composition of claim 11, wherein the at least one second monomer includes a multi-functional acrylate monomer.

13. The photocurable composition of claim 1, wherein the polymerizable material consists essentially of the multi-functional fluorine-containing monomer and the second monomer, the second monomer being a di-functional acrylate monomer, and wherein an amount of the multi-functional fluorine monomer is at least 70 wt % based on the total weight of the polymerizable material.

14. The photocurable composition of claim 1, wherein an amount of the polymerizable material is at least 90 wt % based on the total weight of the photocurable composition.

15. The photocurable composition of claim 1, wherein the photocurable composition further comprises a non-fluorine containing surfactant, and the photocurable composition is essentially free of a fluorine-containing surfactant.

16. The photocurable composition of claim 1, wherein a molecular weight of the multi-functional fluorine-containing monomer is not greater than 600 g/mol.

17. An imprint lithography template comprising a backing layer and a patterned layer overlying the backing layer, wherein the patterned layer is formed from the photocurable composition of claim 1.

18. The imprint lithography template of claim 17, wherein the patterned layer has a reduced modulus of at least 1 GPa.

19. The imprint lithography template of claim 17, wherein a water contact angle of the patterned layer is at least 70°.

20. A method of forming an imprint lithography template, comprising:
applying a layer of a photocurable composition on a backing layer, wherein the photocurable composition comprises a polymerizable material and at least one photoinitiator, the polymerizable material comprises at least one first monomer and at least one second monomer, the at least one first monomer including a multi-functional fluorine-containing monomer and the at least one second monomer being essentially free of fluorine; the polymerizable material comprises fluorine in an amount of at least 30 wt % based on the total weight of the polymerizable material; and a viscosity of the photocurable composition is not greater than 30 mPa·s;
bringing the photocurable composition into contact with a template;
irradiating the photocurable composition with light to form a photo-cured patterned layer; and
removing the template from the patterned layer.
